(19) United States
(12) Patent Application Publication
(10) Pub. No.: US 2017/0195083 A1
(43) Pub. Date: Jul. 6, 2017

(54) INFORMATION PROCESSING APPARATUS

(71) Applicant: FUJITSU LIMITED, Kawasaki-shi (JP)

(72) Inventors: Hiroaki Kameyama, Kawasaki (JP); Shinichi Sazawa, Atsugi (JP)

(73) Assignee: FUJITSU LIMITED, Kawasaki-shi (JP)

(21) Appl. No.: 15/465,940

(22) Filed: Mar. 22, 2017

Related U.S. Application Data
(63) Continuation of application No. PCT/JP2014/075829, filed on Sep. 29, 2014.

(51) Int. Cl. H04L 1/00; H03M 13/00

(52) U.S. Cl. CPC H04L 1/0041; H03M 13/611

(57) ABSTRACT

An information processing apparatus includes a memory and a processor configured to: generate a packet in which one coded data block is stored in a case where the size of the coded data block created from transmission data according to an error correcting code is larger than a predetermined threshold and smaller than a maximum length of the packet, and generate a packet in which a plurality of coded data blocks are stored in a case where the size of the coded data block is equal to or smaller than the predetermined threshold, and transmit a generated packet.

### CROSS-REFERENCE TO RELATED APPLICATION

This application is a continuation application of International Application PCT/JP2014/075829, filed on Sep. 29, 2014, and designated the U.S., the entire contents of which are incorporated herein by reference.

### FIELD

The present invention relates to an information processing apparatus, an information processing method, and an information processing system.

### BACKGROUND

FIG. 1 is a diagram illustrating an example of a process performed at a time of occurrence of packet loss in long distance data transfer. In the long distance data transfer, because the distance between bases A and B is long, communication delay occurs, and the time until an acknowledgement from a receiver apparatus reaches a transmitter apparatus is long. In the case where packet loss occurred on a communication path, the receiver apparatus detects that a packet did not arrive and then transmits a retransmission request to the transmitter apparatus, and the transmitter apparatus retransmits data when the retransmission request is received. Accordingly, when packet loss occurs, it takes even longer time for data to reach the receiver apparatus.

As one method of alleviating delay caused by occurrence of packet loss in a communication path, there is error correcting code technology. The error correcting code is a technology of using redundant data for transmission data so as to allow recovery of original data from data received by the receiver apparatus even if there is occurrence of packet loss. As the error correcting code, there are a parity code, a Reed-Solomon code, an RPS (Random Parity Stream) code, a Raptor code and the like, for example.

For example, FIG. 1 illustrates an example where a parity code is used. The transmitter apparatus combines a packet 1 and a packet 2 to generate a packet P, which is redundant data, and the packet 1, the packet 2, and the packet P are transmitted. If the packet 2 gets lost on the communication path, the receiver apparatus recovers the packet 2 from the packet 1 and the packet P. A retransmission request for the packet 2 and the process of retransmission are thereby omitted, and delay at the time of packet loss may be alleviated.

### PATENT DOCUMENT

[Patent document 1] Japanese Patent Laid-Open No. 2007-258796

[Patent document 2] Japanese Patent Laid-Open No. 2009-188585

However, there are cases where using the error correcting code reduces the transmission efficiency. For example, these are cases of communication of packets of small size, and transfer of small volume files.

FIG. 2 is a diagram illustrating an example of processing of an RPS code. Also, in FIG. 2, examples of a case where the size of input data is large and where the size is small are illustrated. In FIG. 2, a code length N is four.

With the RPS code, first, pieces of input data A, B, and C are combined into one and are then divided into pieces with a code length of N(=4), and sub-data blocks 1, 2, 3, and 4 are created. Next, exclusive OR (XOR) operation is performed on the sub-data blocks 1, 2, 3, and 4, and K (K>N) pieces of coded data blocks, which are the results of the XOR operation, are created. The K coded data blocks are the redundant data. Information about the combination of data blocks for the XOR operation is added to each of the K coded data blocks, and transmission is performed.

The above process is performed regardless of whether the amount of transmission data is large or small. For example, as illustrated in FIG. 2, even if the input data is the data A with a small size, the data A is further divided into smaller four sub-data blocks 1, 2, 3, and 4, and K coded data blocks are created from these sub-data blocks 1 to 4. In the case of the RPS code, a coded data block is created by the exclusive OR operation, and thus, the size of a coded data block is the same as the size of the sub-data block. Accordingly, the proportion of a header portion in one packet is large, and the proportion of a payload portion for storing the coded data block is small. Communication of transmission data of a small size may be transfer of operation information of a remote desktop, or communication for transfer of a file of a small size, for example.

For example, the maximum length of an IP packet is decided to be maximum 1500 bytes. With the RPS code, if the amount of transmission data is large, data may be transmitted by maximally using the payload portion. However, in the case where the amount of transmission data is small, the proportion of the payload portion is small, and even if the same number of packets are transmitted, because the amount of data included in one packet is small, the amount of data that is transmitted per unit time is small. Accordingly, the transfer efficiency is poor, and the maximum value of the data transfer speed is not reached, or the delay is increased, for example. Such problems may occur not just with respect to the RPS code, but also with respect to other error correcting codes according to which K coded data blocks are created from N pieces of transmission data, such as the parity code, the Reed-Solomon code, or the Raptor code.

### SUMMARY

A mode of the present invention is an information processing apparatus including a memory and a processor configured to: generate a packet in which a plurality of coded data blocks are stored depending on a size of the plurality of coded data blocks that are created from transmission data by an error correcting code, and transmit the generated packet.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWING

FIG. 1 is a diagram illustrating an example of a process performed at a time of occurrence of packet loss in long distance data transfer;

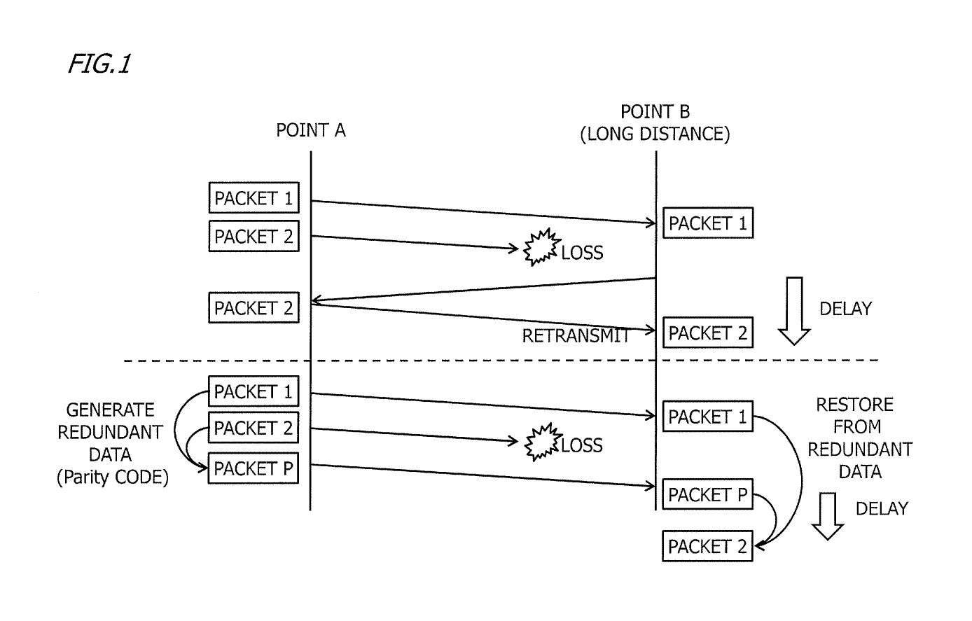

FIG. 2 is a diagram illustrating an example of processing of an RPS code;

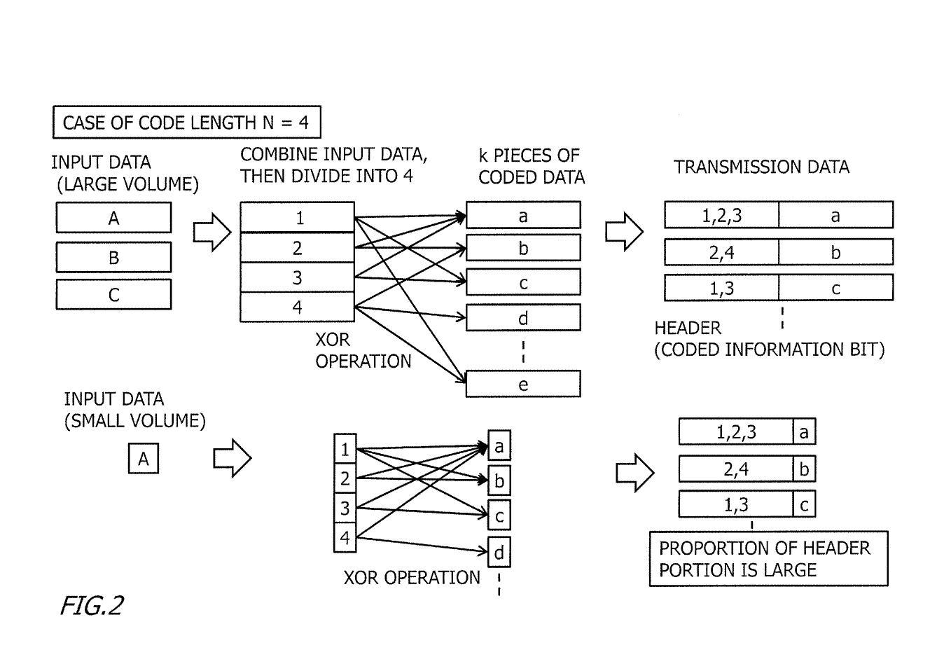

FIG. 3 is a diagram illustrating an example of a process by an information processing apparatus according to a first embodiment;

FIG. 4 is an example of hardware configuration of the information processing apparatus;

FIG. 5 is a diagram illustrating an example of functional configuration of the information processing apparatus;

FIG. 6 is a diagram illustrating an example structure of a transmission packet;

FIG. 7A is an example of a flowchart of an error correcting coding process by a transmitter apparatus;

FIG. 7B is an example of a flowchart of an error correcting coding process by the transmitter apparatus;

FIG. 8 is an example of a flowchart of a process, by a receiver apparatus, of receiving a packet including a coded data block based on an error correcting code.

### DESCRIPTION OF EMBODIMENT

Hereinafter, an embodiment of the present invention will be described with reference to the drawings. The configuration of the embodiment below is merely an example, and the present invention is not limited to the configuration of the embodiment.

### First Embodiment

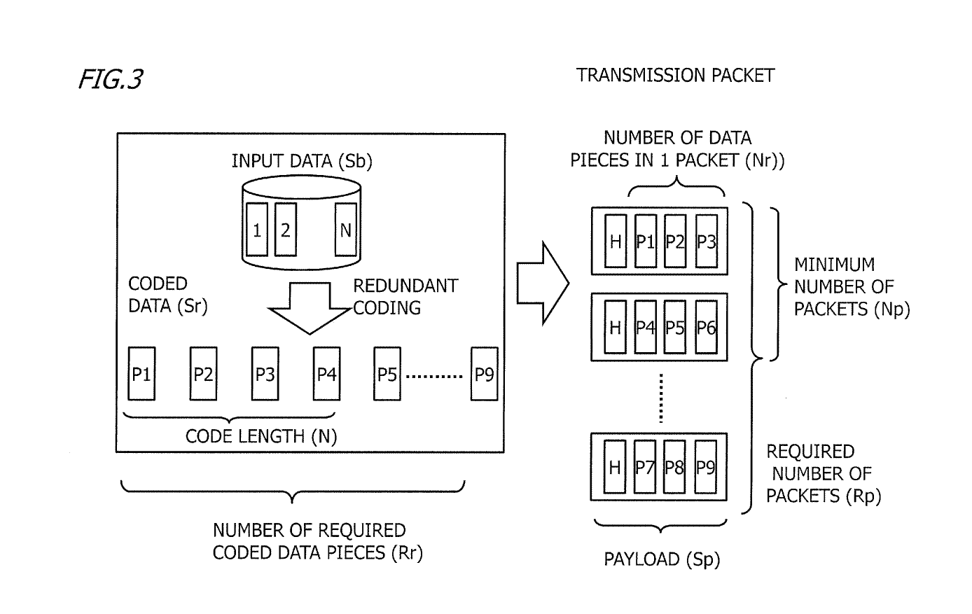

FIG. 3 is a diagram illustrating an example of a process by an information processing apparatus according to a first embodiment. In the first embodiment, the information processing apparatus transmits a plurality of coded data blocks in one packet according to the size of the coded data blocks created from transmission data by an error correcting code. Accordingly, even in communication of transfer data of a small size, a payload portion of a packet may be maximally used, and the transfer efficiency may be increased.

A coded data block is a data block which is created by performing a process based on the error correcting code on transmission data. The coded data block is also referred to as redundant coded data block. Also, an error correcting code which is specifically for recovering lost data may be referred to as an erasure correction code.

In the first embodiment, the information processing apparatus determines the number of coded data blocks to be included in one transmission packet, the number of transmission packets, and the like. Additionally, the error correcting code is not limited to a specific type, but in the first embodiment, description is given citing an example where an RPS code is used.

<Apparatus Configuration>

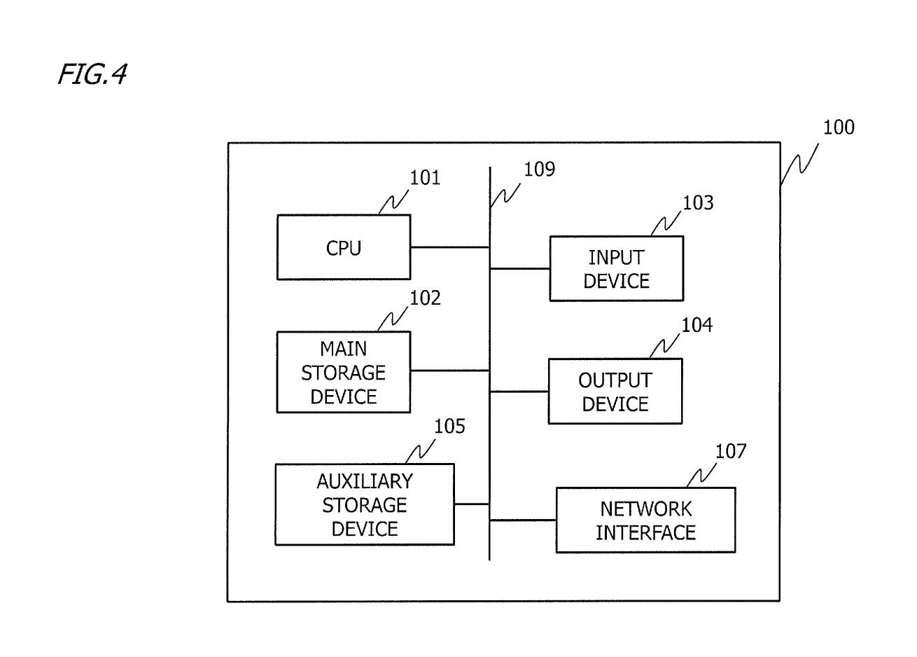

FIG. 4 is an example of hardware configuration of an information processing apparatus 100. The information processing apparatus 100 is a terminal apparatus such as a PC (personal computer), a smartphone, or a tablet terminal, for example. Moreover, the information processing apparatus 100 may be a server at a boundary of a network.

The information processing apparatus 100 includes a CPU (Central Processing Unit) 101, a main storage device 102, an input device 103, an output device 104, an auxiliary storage device 105, and a network interface 107. Moreover, these are interconnected by a bus 109.

The input device 103 is an operation button, a touch panel, a keyboard, or a keypad, for example. Data input from the input device 103 is output to the CPU 101. The input device may also include an audio input device such as a microphone, for example.

The auxiliary storage device 105 stores various programs, and data to be used by the CPU 101 at the time of execution of each program. The auxiliary storage device 105 is a non-volatile memory such as an EPROM (Erasable Programmable ROM), a flash memory, a hard disk drive, or the like. The auxiliary storage device 105 holds the operating system (OS), an error correcting code processing program, and various other application programs, for example. The error correcting code processing program is a program for performing a process based on the error correcting code on data which is transmitted by an application program. The error correcting code processing program is an example of an “information processing program”.

The main storage device 102 is a storage device which provides the CPU 101 with a storage area and a work area for loading programs stored in the auxiliary storage device 105, or which is used as a buffer. The main storage device 102 includes a semiconductor memory such as a ROM (Read Only Memory) or a RAM (Random Access Memory), for example.

The CPU 101 performs various processes by loading, and executing, the OS or various programs held by the auxiliary storage device 105 in the main storage device 102. A plurality of CPUs 101 may be provided instead of one.

The network interface 107 is an interface for input/output of information to/from a network. The network interface 107 includes an interface for connecting to a cable network, and an interface for connecting to a wireless network. For example, the network interface 107 is an NIC (Network Interface Card), a processing circuit for radio signals of a wireless LAN (Local Area Network), Wi-Fi (Wireless Fidelity), WiMAX (Worldwide Interoperability for Microwave Access), LTE (Long Term Evolution), or 3GPP (third-generation mobile phone system), for example. Data and the like received by the network interface 107 are output to the CPU 101.

The output device 104 outputs the result of processing by the CPU 101. The output device 104 includes an audio output device such as speakers, a display, or a printer.

Additionally, the hardware configuration of the information processing apparatus 100 illustrated in FIG. 4 are merely examples, and structural components may be omitted, substituted or added as appropriate according to the embodiment without being limited to the above example. For example, the information processing apparatus 100 may include a removable recording medium drive device, and may execute programs recorded in a removable recording medium. The removable recording medium is a recording medium such as an SD card, a mini SD card, a micro SD card, an USB (Universal Serial Bus) flash memory, a CD (Compact Disc), a DVD (Digital Versatile Disc), a Blu-ray (registered trademark) Disc, or a flash memory card, for example.

Moreover, in the case where the information processing apparatus 100 is a server, the information processing apparatus 100 does not have to be provided with the input device 103, and the output device 104, for example.

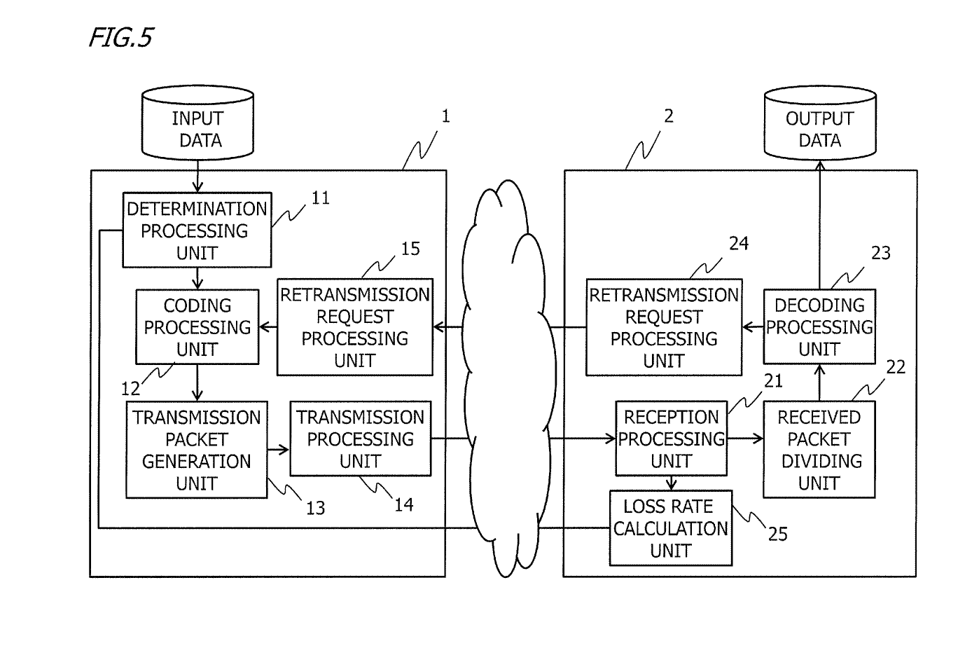

FIG. 5 is a diagram illustrating an example of functional configuration of the information processing apparatus 100. The functional configuration of the information processing apparatus 100 illustrated in FIG. 5 are functional components achieved by execution of an error correcting code processing program by the CPU 101 of the information processing apparatus 100. The error correcting code processing program includes a module related to data transmission processing and a module related to reception processing. Accordingly, in FIG. 5, description is given by distinguishing between a transmission function and a reception function of the information processing apparatus 100. In the following, description will be given taking the transmission function of the information processing apparatus 100 as a transmitter apparatus 1, and the reception function as a receiver apparatus 2.

In the first embodiment, the error correcting code processing program is a program on an application layer of a TCP/IP reference model. However, this is not restrictive, and the error correcting code processing program may be created as a program on a transport layer of the TCP/IP reference model, for example. Also, in the first embodiment, the error correcting code processing program uses an UDP (User Datagram Protocol) as the program on the transport layer. However, this is not restrictive, and the error correcting code processing program may also use a TCP (Transmission Control Protocol) as the program on the transport layer.

As functional components, the transmitter apparatus 1 includes a determination processing unit 11, a coding processing unit 12, a transmission packet generation unit 13, a transmission processing unit 14, and a retransmission request processing unit 15. These functional components are functional components that are achieved by the CPU 101 of the information processing apparatus 100 executing a module related to transmission processing of the error correcting code processing program stored in the auxiliary storage device 105. Additionally, these functional components may alternatively be achieved by a hardware circuit such as an FPGA (field-programmable gate array).

The determination processing unit 11 receives data input from an application program in a predetermined period, and takes the amount of data input in one period as a unit of processing. In the case where there is no data input from the application program in one period, data indicating that there is no data input is taken as the input data. In the following, data which is input during one period of reception of data input will be referred to as input data. Moreover, a sequence number is assigned to the input data.

Furthermore, the determination processing unit 11 receives a packet loss rate from the receiver apparatus 2. The determination processing unit 11 determines a parameter regarding the error correcting code based on the amount of transmission data and the packet loss rate. A parameter regarding the error correcting code is the number of coded data blocks included in one transmission packet, the number of transmission packets, or the number of coded data blocks (K), for example. Details of the process, by the determination processing unit 11, for determining the parameter regarding the error correcting code will be given later.

The coding processing unit 12 performs a process according to the error correcting code on transmission data according to the parameter determined by the determination processing unit 11, and creates coded data blocks. In the first embodiment, the coding processing unit 12 performs a process according to the RPS code. The created coded data blocks are output to the transmission packet generation unit 13.

The transmission packet generation unit 13 receives input of the coded data blocks from the coding processing unit 12, generates a data portion by aggregating the coded data blocks by the number determined by the determination processing unit 11, adds a header according to the error correcting code, and generates a transmission packet. Details of the header according to the error correcting code will be given layer.

The transmission processing unit 14 adds an UDP header and an IP header to the transmission packet created by the transmission packet generation unit 13, and transmits the packet through the network interface 107. Additionally, in the case where the error correcting code processing program uses the TCP, a TCP header is added instead of the UDP header.

The retransmission request processing unit 15 receives a retransmission request from the receiver apparatus 2. For example, the retransmission request includes the sequence number of input data which is the target of the retransmission request. When the retransmission request is received, the retransmission request processing unit 15 instructs the coding processing unit 12 to retransmit the coded data blocks. When the instruction for retransmission is received, coded data blocks are created by the coding processing unit 12 from the corresponding input data, a transmission packet is created by the transmission packet generation unit 13, and the transmission packet is transmitted to the receiver apparatus 2 by the transmission processing unit 14.

As functional components, the receiver apparatus 2 includes a reception processing unit 21, a received packet dividing unit 22, a decoding processing unit 23, a retransmission request processing unit 24, and a loss rate calculation unit 25. These functional components are functional components that are achieved by the CPU 101 of the information processing apparatus 100 executing a module related to reception processing of the error correcting code processing program stored in the auxiliary storage device 105. Additionally, these functional components may alternatively be achieved by a hardware circuit such as an FPGA.

The reception processing unit 21 receives a packet including coded data blocks from the transmitter apparatus 1. The reception processing unit 21 removes the IP header and the UDP header from the received packet, and outputs the received packet from which the IP header and the UDP header have been removed to the received packet dividing unit 22. Also, the reception processing unit 21 outputs information about the received packet to the loss rate calculation unit 25.

The received packet dividing unit 22 receives, from the reception processing unit 21, input of the received packet from which the IP header and the UDP header have been removed. That is, the received packet which is input to the received packet dividing unit 22 includes the header of the RPS code and the data portion. The received packet dividing unit 22 takes out a coded data block from the data portion based on information in the header of the RPS code. The coded data block which is taken out is output to the decoding processing unit 23.

The decoding processing unit 23 performs a decoding process of the RPS code on the coded data block input from the received packet dividing unit 22, acquires the original data, and outputs the original data to a destination application. In the case of failure of decoding of the coded data block, the decoding processing unit 23 issues a notification to the retransmission request processing unit 24.

When notified by the decoding processing unit 23, the retransmission request processing unit 24 transmits a retransmission request to the transmitter apparatus 1. The retransmission request includes the sequence number of input data, retransmission of which is requested, for example.

When the retransmission request is received, the retransmission request processing unit 15 of the transmitter apparatus 1 notifies the coding processing unit 12 of retransmission of the coded data block of the corresponding input data. The coding processing unit 12, the transmission packet generation unit 13, and the transmission processing unit 14 perform the process described above on the input data, and retransmit a transmission packet including a plurality of coded data blocks generated from the input data to the receiver apparatus 2. Additionally, the first embodiment assumes a case of using the RPS code, and the coded data blocks to be retransmitted may be different from those included in the lost packet. Moreover, it is also possible to retransmit some of the coded data blocks generated instead of all the coded data blocks. This is because the original data may be recovered if there is a minimum number of coded data blocks requested for recovery.

The loss rate calculation unit 25 receives input of information about the received packet from the reception processing unit 21, calculates the packet loss rate based on the information, and transmits the calculation result to the transmitter apparatus 1. The method for calculating the packet loss rate is not limited to a particular method, and any known method may be used. Details of an example of the method for calculating the packet loss rate will be given later.

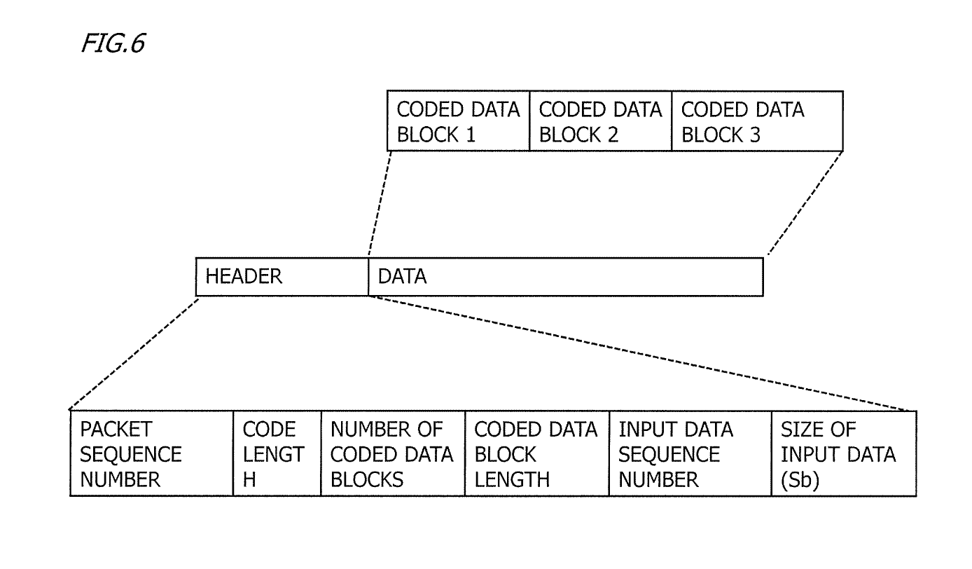

FIG. 6 is a diagram illustrating an example structure of a transmission packet. The transmission packet illustrated in FIG. 6 is a packet that is generated by the transmission packet generation unit 13 of the transmitter apparatus 1. The header portion of the transmission packet is the header of the RPS code including information about the RPS code.

The header portion contains a packet sequence number, a code length, the number of coded data blocks, a coded data block length, an input data sequence number, and the size of input data, for example. The packet sequence number is a serial number which is added to a transmission packet by the transmission packet generation unit 13. One or more coded data blocks are put in the data portion.

The packet loss rate is determined in the following manner, for example. The number of packets M to be used for calculation of the packet loss rate is set in advance in the loss rate calculation unit 25. The loss rate calculation unit 25 calculates until the number of received packets from the transmitter apparatus 1 reaches M, and when the number of received packets reaches M, determines the difference between the minimum value and the maximum value of the packet sequence numbers in the RPS headers of the M received packets. The value obtained by dividing the difference value by the number of packets M to be used for calculation of the packet loss rate is determined to be the packet loss rate. The loss rate calculation unit 25 repeatedly performs the process.

The code length is a code length N of the RPS code. The code length indicates the range of data that can be combined at the time of coding, and more specifically, how many information blocks as a unit of combination is to be provided in input data is indicated. In other words, the code length N is the number of division of one piece of input data.

The number of coded data blocks is the number of coded data blocks included in one transmission packet. The number of coded data blocks is determined by the determination processing unit 11 (described later).

The coded data block length is the size of one coded data block. The coded data block length is determined, by the determination processing unit 11, by dividing the size of input data by the code length.

The sequence number of input data is for identification of the input data, and is a serial number added by the determination processing unit 11 to input data which is received in a predetermined period for receiving input of data, for example. The receiver apparatus 2 may detect a beginning and an end of a block of input data by the sequence number of the input data and the size of the input data.

Additionally, the structure of the transmission packet is merely an example, and information to be included in the header of the RPS code is not limited to those illustrated in FIG. 6. For example, the sequence number of the input data and the size of the input data may be added not in the header of the RPS code, but to each coded data block. Also, the method for calculating the packet loss rate by the loss rate calculation unit 25 is not limited to the method described above.

<Flow of Processing>

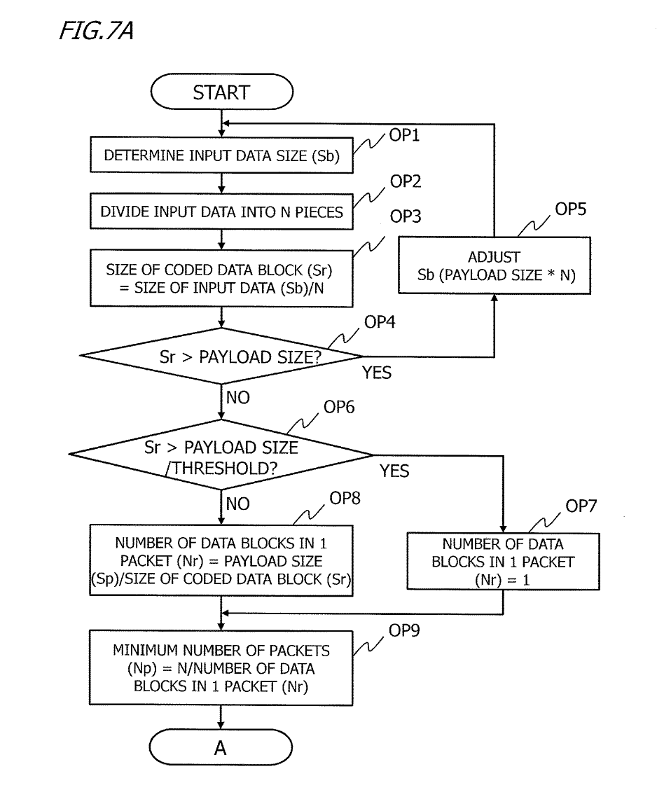

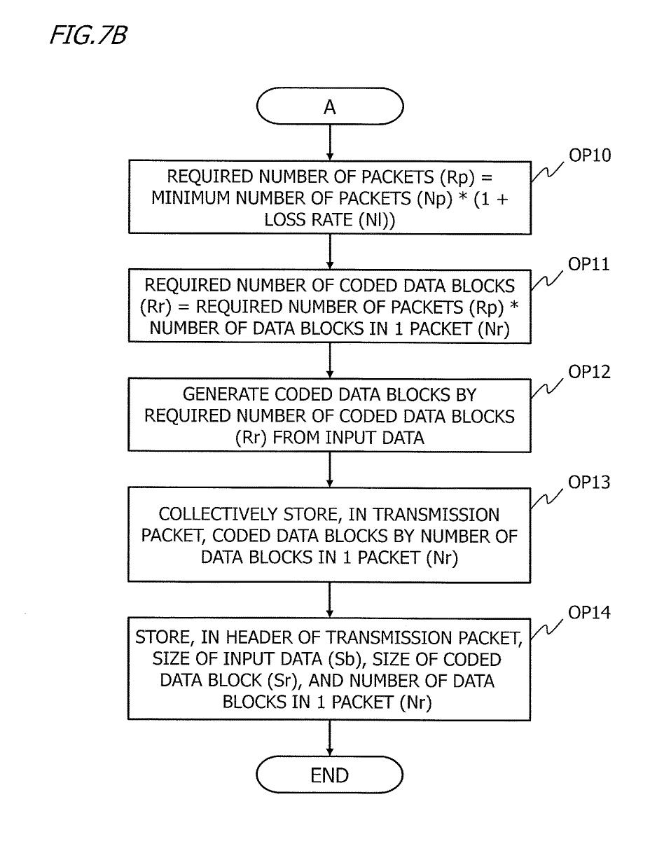

FIGS. 7A and 7B are examples of a flowchart of an error correcting coding process by the transmitter apparatus 1. The flowchart illustrated in FIG. 7A is executed in a predetermined period of receiving input data, after data input from the application program is started.

In OP1, the determination processing unit 11 determines a size of input data (Sb). Then, the process proceeds to OP2.

In OP2, the determination processing unit 11 divides the input data into pieces of code length N, and generates N pieces of sub-data block. Then, the process proceeds to OP3.

In OP3, the determination processing unit 11 divides the size of the input data (Sb) by the code length N, and determines a size of a coded data block (Sr). Then, the process proceeds to OP4.

In OP4, the determination processing unit 11 determines whether the size of the coded data block (Sr) is larger than the size of a payload. This determination is determination of whether one coded data block can be accommodated in one transmission packet. The size of the payload is the value obtained by subtracting the sizes of the IP header, the UDP header, and the header of the RPS code from the maximum length of 1500 bytes of an IP packet, for example. In the case where the size of the coded data block (Sr) is larger than the size of the payload (OP4: YES), the process proceeds to OP5. In the case where the size of the coded data block (Sr) is equal to or smaller than the size of the payload (OP4: NO), the process proceeds to OP6.

In OP5, because the size of the coded data block (Sr) is larger than the size of the payload, and one transmission packet is not able to accommodate one coded data block, the determination processing unit 11 adjusts the size of the input data (Sb). The size of the input data (Sb) is adjusted to be N times the size of the payload. The rest of the input data is included in the next input data of the unit of processing. Next, the process returns to OP1, and the process from OP1 to OP4 is performed again.

In OP6, the determination processing unit 11 determines whether the size of the coded data block (Sr) is larger than the value obtained by dividing the size of the payload by a threshold. This determination is determination of whether two or more coded data blocks may be put in one transmission packet. For example, the threshold is a positive integer of two or three. In the case where the size of the coded data block (Sr) is larger than the value obtained by dividing the size of the payload by the threshold (OP6: YES), the process proceeds to OP7. In the case where the size of the coded data block (Sr) is equal to or smaller than the value obtained by dividing the size of the payload by the threshold (OP6: NO), the process proceeds to OP8.

In OP7, the size of the coded data block (Sr) is larger than the value obtained by dividing the size of the payload by the threshold, and one transmission packet is not able to put two or more coded data blocks. Accordingly, the determination processing unit 11 sets the number of coded data blocks in one packet (Nr) to one. Next, the process proceeds to OP9.

In OP8, the size of the coded data block (Sr) is a value equal to or smaller than the value obtained by dividing the size of the payload by the threshold, and two or more coded data blocks may be put in one transmission packet, and thus, the determination processing unit 11 determines the number of coded data blocks in one packet (Nr) (see FIG. 3). The number of coded data blocks in one packet (Nr) is determined by dividing the size of the payload by the size of the coded data block (Sr). If the value obtained by dividing the size of the payload by the size of the coded data block (Sr) includes a decimal point, a value obtained by truncating the decimal point is taken as the number of coded data blocks in one packet (Nr). Then, the process proceeds to OP9.

In OP9, the determination processing unit 11 determines the minimum number of transmission packets (Np) requested to recover the original data. In the following, the minimum number of transmission packets (Np) requested to recover the original data will be referred to as the minimum number of packets (Np) (see FIG. 3). For example, with the RPS code, the original data can be recovered if there are coded data blocks of the code length N at the minimum. Accordingly, in the first embodiment, the minimum number of packets (Np) is the value obtained by dividing the code length N by the number of coded data blocks in one packet (Nr). In the case where the value obtained by dividing the code length N by the number of coded data blocks in one packet (Nr) includes a decimal point, a value obtained by rounding up the decimal point is taken as the minimum number of packets (Np). Then, the process proceeds to OP10.

In OP10, the determination processing unit 11 determines the number of transmission packets (Rp) which takes the packet loss rate into account. In the following, the number of transmission packets which takes the packet loss rate into account will be referred to as a requested number of packets (Rp) (see FIG. 3). The requested number of packets (Rp) is a value obtained by multiplying the minimum number of packets (Np) by (1+packet loss rate (Nl)), for example. In the case where a value obtained by multiplying the minimum number of packets (Np) by (1+packet loss rate (Nl)) includes a decimal point, a value obtained by truncating the decimal point is taken as the requested number of packets (Rp). Additionally, this is not restrictive, and a value obtained by rounding up the decimal point may alternatively be taken as the requested number of packets (Rp). Moreover, the method for determining the requested number of packets (Rp) is not limited to the method above, and a value obtained by multiplying the minimum number of packets (Np) by 1/(1−packet loss rate (Nl)) may alternatively be used. Next, the process proceeds to OP11.

In OP11, the determination processing unit 11 determines the number of coded data blocks (Rr) to be put in packets of the requested number of packets (Rp). In the following, the number of coded data blocks (Rr) to be put in the packets of the requested number of packets (Rp) will be referred to as the requested number of coded data blocks (Rr) (see FIG. 3). The requested number of coded data blocks (Rr) is a value obtained by multiplying the requested number of packets (Rp) by the number of data blocks in one packet (Nr). Next, the process proceeds to OP12.

In OP12, the coding processing unit 12 generates coded data blocks by the requested number of coded data blocks (Rr) from the input data based on the RPS code. Then, the process proceeds to OP13.

In OP13, the transmission packet generation unit 13 generates a data portion of a transmission packet by collecting together the coded data blocks by the number of data blocks in one packet (Nr). Then, the process proceeds to OP14.

In OP14, the transmission packet generation unit 13 puts, in the header portion of the transmission packet, information pieces such as the size of the input data (Sb), the size of the coded data block (Sr), and the number of data blocks in one packet (Nr) (see FIG. 6), and generates the transmission packet. Then, the transmission packet is output to the transmission processing unit 14, and is transmitted to the receiver apparatus 2, and the process illustrated in FIG. 7B is ended.

Additionally, the processes illustrated in FIGS. 7A and 7B are merely examples, and may be changed as appropriate. For example, the number of coded data blocks to be included in one packet (Nr), the minimum number of packets (Np), and the requested number of packets (Rp) may be fixed values set in advance, and the process from OP8 to OP10 may be omitted. Furthermore, in the case where the size of input data (Sb) in one predetermined period for reception of data input is smaller than a predetermined threshold, start of the flowchart in FIG. 7A may be placed in standby until the size of the input data (Sb) exceeds the predetermined threshold.

Furthermore, for example, the condition for starting the processes illustrated in FIGS. 7A and 7B may be specifically for a predetermined application. A predetermined application is an application for a small amount of transfer data such as in the case of a remote desktop, for example. In this case, it is known in advance that the size of input data (Sb) is small, and that the coded data block is smaller than a value obtained by dividing the size of the payload by the threshold, and the process in OP4 may be omitted.

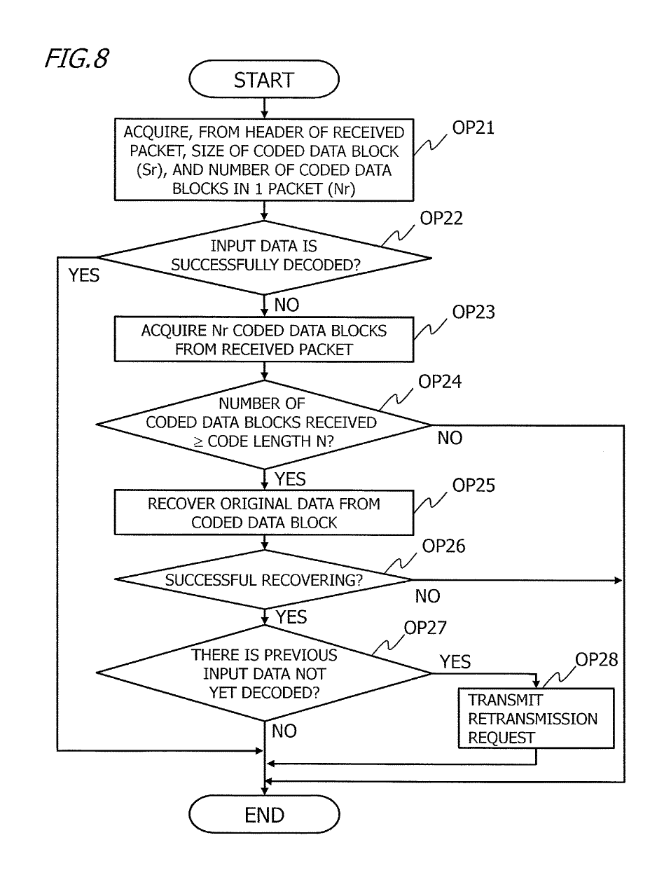

FIG. 8 is an example of a flowchart of a process, by the receiver apparatus 2, of receiving a packet including a coded data block coded by an error correcting code. The flowchart illustrated in FIG. 8 is started when the receiver apparatus 2 receives a packet including the coded data block coded by the error correcting code processing program from the transmitter apparatus 1.

In OP21, the received packet dividing unit 22 acquires, from the header of the RPS code of the received packet, the size of the coded data block (Sr), the number of coded data blocks included in one packet (Nr), the code length N, and the sequence number of the input data. Then, the process proceeds to OP22.

In OP22, the received packet dividing unit 22 determines whether decoding of input data corresponding to the sequence number of input data acquired from the received packet has been successful. In the case where decoding of the corresponding input data has already succeeded (OP22: YES), the process of decoding the corresponding input data does not have to be performed, and the process illustrated in FIG. 8 is ended, and the process is started for the next received packet. In the case where decoding of the corresponding input data has not yet succeeded (OP22: NO), the process proceeds to OP23.

In OP23, the received packet dividing unit 22 acquires Nr coded data blocks from the received packet. The size of the coded data blocks is the size of coded data block (Sr) acquired in OP21. The acquired coded data blocks are output to the decoding processing unit 23. Next, the process proceeds to OP24.

In OP24, the decoding processing unit 23 determines whether the number of coded data blocks received with respect to the corresponding input data is equal to or more than the code length N. This determination is determination of whether the number of the received coded data blocks has reached the minimum number requested for recovery of the original data. In the case where the number of coded data blocks received with respect to the corresponding input data is equal to or more than the code length N (OP24: YES), the process proceeds to OP25. In the case where the number of coded data blocks received with respect to the corresponding input data is less than the code length N (OP24: NO), the decoding process is not performed, and the process illustrated in FIG. 8 is ended, and the process is started for the next received packet.

In OP25, the decoding processing unit 23 decodes the coded data blocks, and recovers the original data. In the first embodiment, the method of recovery is according to the RPS code. Then, the process proceeds to OP26.

In OP26, the decoding processing unit 23 determines whether recovery of the original data has succeeded. In the case of success of recovery of the original data (OP26: YES), the process proceeds to OP27. In the case of failure of recovery of the original data (OP26: NO), the process illustrated in FIG. 8 is ended, and the process is started for the next received packet.

In OP27, the decoding processing unit 23 determines whether there is previous input data which is not decoded. For example, in the case of failure of decoding, the process is suspended, and the coded data block and the like of the input data are buffered. This determination is performed based on whether or not there is a coded data block of previous input data in the buffer, for example. In the case where there is previous input data which is not yet decoded (OP27: YES), the process proceeds to OP28. In the case where there is no previous input data which is not yet decoded (OP27: NO), the process illustrated in FIG. 8 is ended, and the process is started for the next received packet.

In OP28, the decoding processing unit 23 notifies the retransmission request processing unit 24 of the sequence number of the input data which is not yet decoded, and the retransmission request processing unit 24 transmits a retransmission request for the input data to the transmitter apparatus 1. The retransmission request includes the sequence number of the input data which is not yet decoded, for example. Then, the process illustrated in FIG. 8 is ended, and the process is started for the next received packet.

Additionally, the process illustrated in FIG. 8 is merely an example, and the process by the receiver apparatus 2 is not limited thereto. For example, in the case where decoding of input data is not performed for the last received packet in the communication with the transmitter apparatus 1, or in the case where there is not a minimum number of coded data blocks requested for decoding, the retransmission request may be issued for the corresponding input data after a lapse of a predetermined time.

<Operations and Effects of First Embodiment>

In the first embodiment, in the case of applying error correcting code on transmission data, the transmitter apparatus puts a plurality of redundant coded data blocks in one packet according to the size of the coded data blocks, and transmits the same. Accordingly, even in the case of communication by an application for a small amount of transfer data, the data portion of one packet may be used to a value close to the maximum length, and the overhead may be reduced. The amount of coded data blocks to be transmitted in one packet is increased, and the transfer speed is increased. Therefore, according to the first embodiment, it is possible to increase the data transfer efficiency in communication of a small amount of transfer data where the error correcting code is used.

According to the information processing apparatus, the information processing method, and the information processing system of the disclosure, it is possible to increase the transfer efficiency in communication of transfer data of a small size when an error correcting code is used.

<Others>

In the first embodiment, description is given for a case where the RPS code is used as an example of the error correcting code. However, also in the case where another error correcting code is used, the transmitter apparatus 1 may put a plurality of redundant coded data blocks in one packet according to the size of the coded data blocks and transmit the same, and the receiver apparatus 2 may acquire a plurality of redundant coded data blocks from the packet. An error correcting code other than the RPS code may be used by changing the processes by the determination processing unit 11, the coding processing unit 12, and the transmission packet generation unit 13 of the transmitter apparatus 1, and the received packet dividing unit 22, and the decoding processing unit 23 of the receiver apparatus 2 to processes according to the corresponding error correcting code.

Furthermore, in the first embodiment, the information processing apparatus 100 is assumed to be a terminal apparatus, but the information processing apparatus 100 may be a gateway apparatus, a server or the like. For example, in the case where the information processing apparatus 100 is a gateway apparatus accommodating a plurality of terminals, the input data is received data from the plurality of terminals. Additionally, in the case where the information processing apparatus 100 is a gateway apparatus, the transmitter apparatus 1 creates coded data blocks from data received from a terminal and transmits the same to the receiver apparatus 2 without identifying the source and destination IP addresses of the data, the source and destination port numbers, and the like. The receiver apparatus 2 recovers the original data from the coded data blocks, refers to the information included in the original data, and transfers the data to the destination terminal.

Moreover, in the first embodiment, one transmitter apparatus 1 performs processes of determining the parameter regarding the error correcting code, creating coded data blocks, and the like, but the processes may be performed by a plurality of apparatuses in a decentralized manner. The processes by the receiver apparatus 2 may also be performed by a plurality of apparatuses in a decentralized manner.

<Recording Medium>

A program for causing a computer or another machine or apparatus (hereinafter, “computer or the like”) to provide any of the above-described functions can be recorded into a recording medium that can be read by a computer or the like. The program in the recording medium is read into the computer or the like and executed, enabling provision of the function.

Here, the recording medium that can be read by the computer or the like refers to a non-transitory recording medium that can store information such as data and/or programs by means of electrical, magnetic, optical, mechanical or chemical action and can be read from the computer or the like. From among such recording mediums, ones that can be removed from the computer or the like include, for example, a flexible disk, a magneto-optical disk, a CD-ROM, a CD-R/W, DVD, a Blu-ray disk, a DAT, an 8 mm tape and a memory card such as a flash memory. Also, recording mediums fixed to the computer or the like include, e.g., a hard disk and a ROM (read-only memory). Furthermore, a SSD (solid state drive) can be used as either a recording medium that can be removed from the computer or the like or a recording medium fixed to the computer or the like.

All examples and conditional language provided herein are intended for the pedagogical purposes of aiding the reader in understanding the invention and the concepts contributed by the inventor to further the art, and are to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus comprising:
a memory, and
a processor configured to:
generate a packet in which a plurality of coded data blocks are stored depending on a size of the plurality of coded data blocks that are created from transmission data by an error correcting code; and
transmit the generated packet including the plurality of coded data blocks.

2. The information processing apparatus according to claim 1, wherein,
when the size of the coded data blocks is larger than a predetermined threshold and smaller than a maximum length of a packet, the processor is configured to put one coded data block in one packet, and
when the size of the coded data blocks is equal to or smaller than the predetermined threshold, the processor is configured to put a plurality of the coded data blocks in one packet.

3. The information processing apparatus according to claim 1, wherein the processor is further configured to determine the size of the coded data blocks by dividing a size of the transmission data by a code length N of the error correcting code, and determine the number of coded data blocks to be put in one packet.

4. The information processing apparatus according to claim 3, wherein the processor is configured to determine the number of packets to be transmitted, by using a packet loss rate.

5. An information processing method of an information processing apparatus including a processor and a memory, the method executed by the processor, comprising:
generating a packet in which a plurality of coded data blocks are stored depending on a size of the plurality of coded data blocks that are created from transmission data by an error correcting code, and
transmitting the generated packet including the plurality of coded data blocks.

6. An information processing system comprising:
a transmitter apparatus including a memory and a processor configured to:
generate a packet in which a plurality of coded data blocks are stored depending on a size of the plurality of coded data blocks that are created from transmission data by an error correcting code, and
transmit the generated packet including the plurality of coded data blocks; and
a receiver apparatus including a memory and a processor configured to:
receive the packet from the transmitter apparatus,
acquire a plurality of coded data blocks from the packet,
decode, by the error correcting code, the plurality of coded data blocks acquired from the packet, and
acquire the transmission data.
